(19) United States
(12) Patent Application Publication
(10) Pub. No.: US 2026/0213728 A1
(43) Pub. Date: Jul. 23, 2026

(54) ELECTROACOUSTIC TRANSDUCER

(71) Applicant: Yusuke SHIMOYAMA, Tokyo (JP)

(72) Inventor: Yusuke SHIMOYAMA, Tokyo (JP)

(73) Assignee: MITSUMI ELECTRIC CO., LTD., Tokyo (JP)

(21) Appl. No.: 19/449,672

(22) Filed: Jan. 15, 2026

(30) Foreign Application Priority Data
Jan. 21, 2025 (JP) 2025-008638

(51) Int. Cl. H03H 9/13; H03H 9/17; H04R 3/00; H04R 17/00

(52) U.S. Cl. CPC H03H 9/13; H03H 9/17; H04R 3/00; H04R 17/00; H04R 2201/003; H04R 2400/11

(57) ABSTRACT

An electroacoustic transducer includes a chip including a movable portion, a frame portion surrounding the movable portion, and a connecting portion connecting the movable portion and the frame portion, a piezoelectric element including a piezoelectric layer stacked on the connecting portion, and a first electrode and a second electrode configured to apply a voltage to the piezoelectric layer, and a bias generation circuit configured to adjust a bias voltage of a drive signal to be applied between the first electrode and the second electrode.

### CROSS-REFERENCE TO RELATED APPLICATIONS

This application is based upon and claims priority to Japanese Patent Application No. 2025-008638, filed on Jan. 21, 2025, the entire contents of which are incorporated herein by reference.

### TECHNICAL FIELD

The present disclosure relates to electroacoustic transducers.

### BACKGROUND

A known electroacoustic transducer includes a speaker using a micro electro mechanical systems (MEMS) device. It is known to use a piezoelectric element as a drive section of the MEMS (refer to U.S. Patent Application Publication No. 2019/0268689 and German Utility Model No. 202022100478, for example). It is also known to stack a stress counter film to induce compressive stress in a piezoelectric film of the piezoelectric element (refer to Japanese Laid-Open Patent Publication No. 2018-54908, for example).

In order to suppress depolarization of the piezoelectric film of the piezoelectric element, a positive drive signal is applied to the piezoelectric element. However, electroacoustic conversion characteristics, such as sound pressure, linearity, or the like deteriorate near a maximum value of the drive signal.

### SUMMARY

One aspect of the present disclosure provides an electroacoustic transducer which can suppress deterioration of the electroacoustic conversion characteristics.

According to one aspect of embodiments of the present disclosure, an electroacoustic transducer includes a chip including a movable portion, a frame portion surrounding the movable portion, and a connecting portion connecting the movable portion and the frame portion; a piezoelectric element including a piezoelectric layer stacked on the connecting portion, and a first electrode and a second electrode configured to apply a voltage to the piezoelectric layer; and a bias generation circuit configured to adjust a bias voltage of a drive signal to be applied between the first electrode and the second electrode.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic diagram illustrating a MEMS device according to a first embodiment;

FIG. 2 is a diagram illustrating a drive signal S with respect to time;

FIG. 3A, FIG. 3B, and FIG. 3C are cross sectional views of a MEMS device according to a first comparative example;

FIG. 4A, FIG. 4B, and FIG. 4C are cross sectional views of the MEMS device according to the first embodiment;

FIG. 5 is a disassembled perspective view of an electroacoustic transducer according to a second embodiment;

FIG. 6 is a plan view of a chip according to the second embodiment;

FIG. 7 is a cross sectional view of the chip according to the second embodiment;

FIG. 8 is a cross sectional view of the chip according to the second embodiment;

FIG. 9 is a diagram illustrating a displacement with respect to a voltage in samples A and B of the second embodiment;

FIG. 10 is a diagram illustrating a height with respect to a position X of the sample A of the second embodiment;

FIG. 11 is a diagram illustrating a displacement with respect to a phase of the sample A of the second embodiment;

FIG. 12 is a diagram illustrating the displacement with respect to the phase in the sample A of the second embodiment;

FIG. 13 is a diagram illustrating a THD with respect to a frequency of the samples A and B of the second embodiment;

FIG. 14 is a diagram illustrating a SPL with respect to the frequency of the samples A and B of the second embodiment;

FIG. 15A is a cross sectional view of the electroacoustic transducer according to a third embodiment;

FIG. 15B is a cross sectional view of the electroacoustic transducer according to the third embodiment;

FIG. 16 is a diagram illustrating the THD with respect to the frequency of a sample without a step and a sample with a step;

FIG. 17 is a diagram illustrating the SPL with respect to the frequency of the sample without the step and the sample with the step;

FIG. 18 is a cross sectional view of the electroacoustic transducer according to a first modification of the third embodiment;

FIG. 19 is a cross sectional view of the electroacoustic transducer according to a second modification of the third embodiment;

FIG. 20 is a schematic diagram illustrating the drive signal S with respect to the time in a fourth embodiment;

FIG. 21 is a diagram illustrating the THD with respect to the frequency of samples with varied bias voltages;

FIG. 22 is a diagram illustrating the SPL with respect to the frequency of the samples with the varied bias voltages;

FIG. 23 is a diagram illustrating the electroacoustic transducer according to a fifth embodiment;

FIG. 24 is a circuit diagram illustrating a first example of the bias generation circuit in the fifth embodiment;

FIG. 25 is a circuit diagram illustrating a second example of the bias generation circuit in the fifth embodiment;

FIG. 26 is a circuit diagram illustrating a first example of a drive circuit in the fifth embodiment;

FIG. 27 is a circuit diagram illustrating a second example of the drive circuit in the fifth embodiment;

FIG. 28 is a circuit diagram illustrating a third example of the drive circuit in the fifth embodiment; and

FIG. 29A, FIG. 29B, and FIG. 29C are diagrams illustrating signals with respect to the time in the third example of the drive circuit according to the third embodiment.

### DETAILED DESCRIPTION

Hereinafter, embodiments of the present disclosure will be described in detail with reference to the drawings. The following embodiments are merely examples for embodying the technical idea of the present disclosure, and the present disclosure is not limited to the configurations and numerical values described herein. In the drawings, the same components or constituent elements are designated by the same reference numerals, and a redundant description thereof may be omitted, as appropriate. The size, positional relationship, or the like of each member illustrated in the drawings may be exaggerated to facilitate understanding of the present disclosure.

### First Embodiment

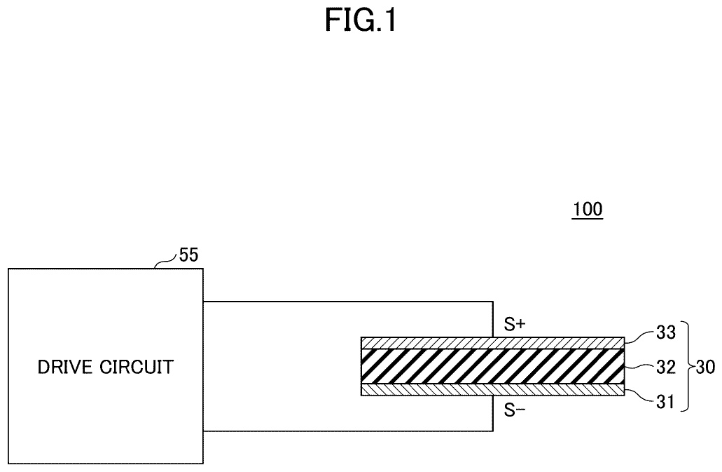

FIG. 1 is a schematic diagram of a MEMS device according to a first embodiment. As illustrated in FIG. 1, a MEMS device 100 includes a piezoelectric element 30. The piezoelectric element 30 includes a piezoelectric layer 32, and a pair of electrodes 31 and 33. The pair of electrodes 31 and 33 sandwich the piezoelectric layer 32 therebetween. A drive circuit 55 applies drive signals S− and S+ to the piezoelectric layer 32 via the electrodes 31 and 33, respectively.

After the MEMS device 100 is manufactured using semiconductor manufacturing processes, a direct current (DC) voltage is applied to the piezoelectric layer 32. For example, a positive voltage is applied to the electrode 33 with respect to (or relative to) the electrode 31. This application of the positive voltage causes spontaneous polarization of the piezoelectric layer 32. The piezoelectric layer 32 maintains the polarized state thereof even when the DC voltage is no longer applied to the piezoelectric layer 32. For this reason, the piezoelectric layer 32 can maintain a high piezoelectric performance. However, when a voltage in a direction opposite to the direction of the spontaneous polarization is applied to the piezoelectric layer 32 (for example, when a negative voltage is applied to the electrode 33 with respect to the electrode 31), the spontaneous polarization disappears. This state in which the spontaneous polarization disappears is referred to as depolarization. In particular, the depolarization is likely to occur in a piezoelectric body (or material) having a perovskite crystal structure.

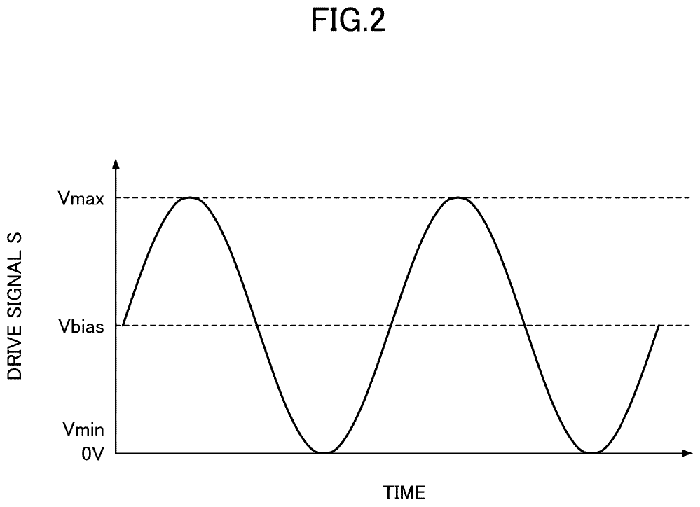

FIG. 2 is a diagram illustrating the drive signal S with respect to time. The drive signal S corresponds to a difference {(S+)−(S−)} of the drive signals S+ and S− in FIG. 1. The drive signal S has a maximum value Vmax and a minimum value Vmin. The maximum value Vmax and the minimum value Vmin are an upper limit value and a lower limit value of a recommended drive voltage, for example. A bias voltage Vbias is a DC component of the drive signal S. As illustrated in FIG. 2, the bias voltage Vbias is positive and the minimum value Vmin is 0 V. Accordingly, because the positive drive signal S is applied to the piezoelectric layer 32, the depolarization can be suppressed.

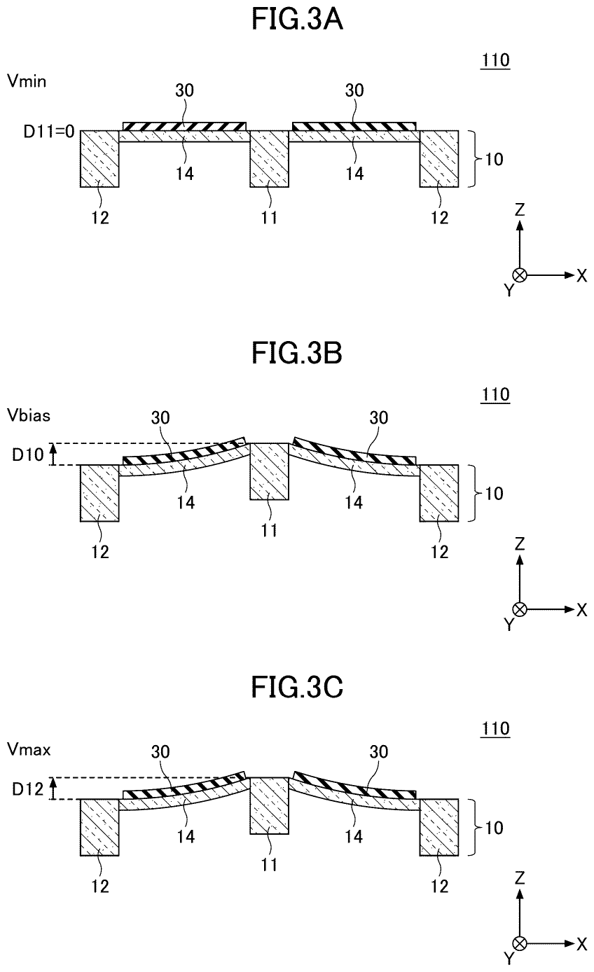

FIG. 3A, FIG. 3B, and FIG. 3C are cross sectional views of a MEMS device according to a first comparative example. FIG. 3A, FIG. 3B, and FIG. 3C are schematic views for cases where the applied drive signal S is Vmin, Vbias, and Vmax, respectively. A thickness direction of a chip 10 is defined as a Z direction, and directions perpendicular to the Z direction are defined as an X direction and a Y direction.

As illustrated in FIG. 3A, FIG. 3B, and FIG. 3C, in a MEMS device 110 according to the first comparative example, the chip 10 includes a movable portion 11, a frame portion 12, and a connecting portion 14. The movable portion 11 is movable in the Z direction in response to the drive signal S. The movable portion 11 vibrates a diaphragm, and an electroacoustic transducer emits sound. The frame portion 12 surrounds the movable portion 11 on an XY plane. The connecting portion 14 connects the movable portion 11 and the frame portion 12. The connecting portion 14 is thinner than the movable portion 11 and the frame portion 12. Accordingly, the connecting portion 14 is easily bent when stress is applied in the Z direction. A piezoelectric element 30 is provided on a surface of the connecting portion 14. The piezoelectric element 30 may be provided on either a +Z surface or a −Z surface of the connecting portion 14.

As illustrated in FIG. 3A, when the minimum value Vmin (for example, 0 V) is applied to the piezoelectric element 30 as the drive signal S, the chip 10 is in a flat state. In the flat state, a principal surface of the chip 10 is parallel to the XY plane. For example, a +Z surface of the movable portion 11, the +Z surface of the connecting portion 14, and a +Z surface of the frame portion 12 are located on the same XY plane. In the flat state, a displacement D11 of the movable portion 11 with respect to the frame portion 12 is 0. The XY plane does not represent a strictly geometrical plane, and tolerates distortions on the order of manufacturing errors. After the piezoelectric layer 32 is spontaneously polarized, the displacement D11 becomes a small positive value so that the movable portion 11 of the chip 10 becomes positioned slightly in the +Z direction from the flat state, but the displacement D11 is assumed to be D11=0 for the sake of convenience.

As illustrated in FIG. 3B, when the bias voltage Vbias is applied to the piezoelectric element 30 as the drive signal S, the piezoelectric layer 32 of the piezoelectric element 30 is under compressive stress. The movable portion 11 and the connecting portion 14 warp (or bend) in the +Z direction. For this reason, the movable portion 11 is displaced in the +Z direction. A displacement D10 of the movable portion 11 with respect to the frame portion 12 is positive when the +Z direction is assumed to be positive. The displacement D10 corresponds to the position of the +Z surface of the movable portion 11 in the Z direction with respect to the +Z surface of the frame portion 12, for example.

As illustrated in FIG. 3C, when the maximum value Vmax is applied to the piezoelectric element 30 as the drive signal S, the piezoelectric layer 32 of the piezoelectric element 30 is under higher compressive stress. For this reason, the movable portion 11 is displaced further in the +Z direction. A displacement D12 of the movable portion 11 with respect to the frame portion 12 is positive. The displacement D12 is larger than the displacement D10. However, when the drive signal S becomes large, the displacement saturates. Hence, a difference between the displacements D12 and D10 is smaller than a difference between the displacements D10 and D11.

As described above, in the MEMS device 110 according to the first comparative example, the displacement saturates even when the drive signal S becomes large. For this reason, when an amplitude of the drive signal S becomes large, electroacoustic conversion characteristics, such as sound pressure, linearity, or the like of the electroacoustic transducer deteriorate when the amplitude of the drive signal S becomes large.

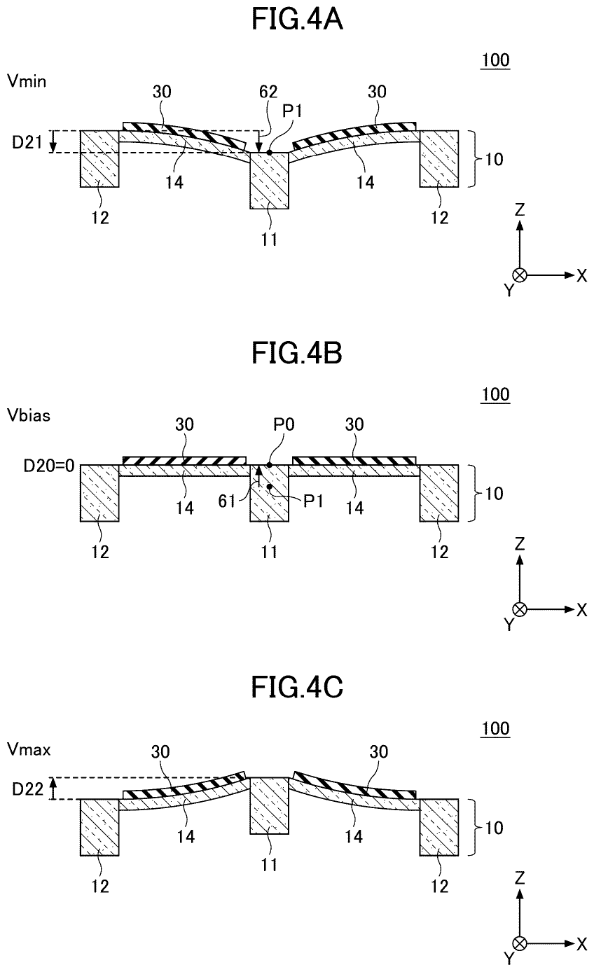

FIG. 4A, FIG. 4B, and FIG. 4C are cross sectional views of the MEMS device according to the first embodiment. FIG. 4A, FIG. 4B, and FIG. 4C are schematic views for cases where the applied drive signal S is Vmin, Vbias, and Vmax, respectively.

As illustrated in FIG. 4A, FIG. 4B, and FIG. 4C, the MEMS device 100 according to the first embodiment includes a chip 10 and the piezoelectric element 30. The chip 10 includes a movable portion 11, a frame portion 12 (first frame portion) surrounding the movable portion 11, and a connecting portion 14 (first connecting portion) connecting the movable portion 11 and the frame portion 12.

As illustrated in FIG. 4A, when the drive signal S has the minimum value Vmin (for example, 0 V), a position of the movable portion 11 with respect to the frame portion 12 is located in the −Z direction from the position in the flat state. That is, a displacement D21 of the movable portion 11 from the flat state is negative.

As illustrated in FIG. 4B, when the bias voltage Vbias is applied to the piezoelectric element 30 as the drive signal S, the movable portion 11 is displaced in the +Z direction from the position illustrated in FIG. 4A. A displacement D20 of the movable portion 11 with respect to the frame portion 12 is substantially zero.

As illustrated in FIG. 4C, when the maximum value Vmax is applied to the piezoelectric element 30 as the drive signal S, the movable portion 11 is displaced in the +Z direction. A displacement D22 of the movable portion 11 with respect to the frame portion 12 is positive. In the MEMS device 100 according to the first embodiment, the displacement of the movable portion 11 with respect to the frame portion 12 is negative when the drive signal S is small and is positive when the drive signal S is large, with drive signal S centered on the bias voltage Vbias. For this reason, even when the amplitude of the drive signal S becomes large, the displacement is less likely to saturate. Hence, it is possible to suppress deterioration of the electroacoustic conversion characteristics, such as sound pressure, linearity, or the like of the electroacoustic transducer, such as a MEMS speaker or the like.

According to the first embodiment, the position of the movable portion 11 with respect to the frame portion 12 when the drive signal S is not applied to the piezoelectric elements 30 is defined as P1, as illustrated in FIG. 4A. The position of the movable portion 11 with respect to the frame portion 12 when the bias voltage Vbias is applied to the piezoelectric elements 30 as the drive signal S is defined as P0, as illustrated in FIG. 4B. In this state, a direction from the position P1 to the position P0 is defined as a first direction 61. As illustrated in FIG. 4A, when the minimum value Vmin is applied to the piezoelectric element 30 as the drive signal S, the movable portion 11 is positioned in a second direction 62 opposite to the first direction 61 with respect to the flat state of the chip 10. Thus, it is possible to suppress the deterioration of electroacoustic conversion characteristics, such as the sound pressure, the linearity, or the like of the electroacoustic transducer.

In addition, when the drive signal S is not applied to the piezoelectric element 30, the movable portion 11 is located in the second direction 62 with respect to the flat state of the chip 10. Hence, it is possible to suppress the deterioration of the electroacoustic conversion characteristics, such as the sound pressure, the linearity, or the like of the electroacoustic transducer without having to set the drive signal S to be negative.

In the example illustrated in FIG. 4A, FIG. 4B, and FIG. 4C, the first direction 61 is the +Z direction and the second direction is the −Z direction is described, but the first direction 61 may be the −Z direction and the second direction may be the −Z direction.

When the bias voltage Vbias is applied to the piezoelectric element 30 as the drive signal S, the chip 10 is preferably in the flat state. Accordingly, the displacement is less likely to saturate in both cases where the drive signal S is positive and the drive signal S is negative. Thus, it is possible to suppress the deterioration of electroacoustic conversion characteristics, such as the sound pressure, the linearity, or the like of the electroacoustic transducer.

When the bias voltage Vbias is applied to the piezoelectric element 30 as the drive signal S, the chip 10 is not necessarily in the flat state, but is preferably in a state close to the flat state. For example, in FIG. 4A, a displacement D1 of the movable portion 11 in the first direction 61 from the flat state when the minimum value Vmin is applied to the piezoelectric element 30 as the drive signal S is defined as a displacement D21. In FIG. 4C, a displacement D2 of the movable portion 11 in the first direction 61 from the flat state when the maximum value Vmax is applied to the piezoelectric elements 30 as the drive signal S is defined as a displacement D22. In this case, in FIG. 4B, a displacement D20 of the movable portion 11 in the first direction 61 from the flat state when the bias voltage Vbias is applied to the piezoelectric element 30 as the drive signal S is preferably −0.25×|D22−D21| or greater and +0.25×|D22−D21| or less, more preferably −0.15×|D22−D21| or greater and +0.15×|D22−D21| or less, and even more preferably −0.1×|D22−D21| or greater and +0.1×|D22−D21| or less.

### Second Embodiment

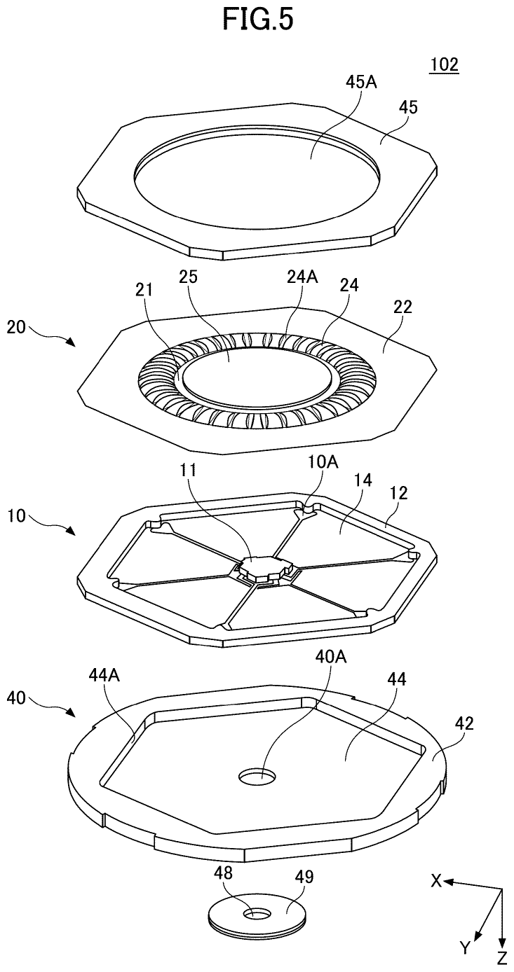

A second embodiment is an example of the electroacoustic transducer. FIG. 5 is a disassembled perspective view of the electroacoustic transducer according to the second embodiment. As illustrated in FIG. 5, an electroacoustic transducer 102 according to the second embodiment includes a substrate 40, a chip 10, a membrane 20, a diaphragm 25, a lid member 45, and a mesh 48. The electroacoustic transducer 102 is an earphone or a fixed (or installed) speaker.

The substrate 40 includes a frame portion 42 and a thin film portion 44. A −Z surface of the thin film portion 44 is located in the +Z direction from a −Z surface of the frame portion 42. As a result, a cavity 44A surrounded by the frame portion 42 is formed on the −Z side of the thin film portion 44. When viewed in the Z direction, the cavity 44A overlaps the movable portion 11 and the connecting portion 14 of the chip 10. Accordingly, even when the movable portion 11 and the connecting portion 14 are driven, it is possible to restrict the movable portion 11 and the connecting portion 14 from coming into contact with the substrate 40. The substrate 40 may have an interconnect layer.

The substrate 40 may be provided with a through hole 40A. The through hole 40A can be provided at a central portion of the thin film portion 44 in a plan view, for example. The through hole 40A serves as an air path for air inflow and outflow with respect to an inner side of the substrate 40. In this case, because the air can enter and exit through the through hole 40A, it is possible to reduce air resistance when the movable portion 11 of the chip 10 moves. Hence, the movable portion 11 can easily move, and the displacement of the movable portion 11 can be increased.

The substrate 40 is a glass epoxy substrate, for example. The substrate 40 may be an insulating substrate, such as a silicon substrate, a ceramic substrate, or the like. The interconnect layer is a metal layer, such as a gold layer, a copper layer, or the like. A thickness of the substrate 40 is 0.2 mm to 0.6 mm, for example. A depth of the frame portion 42 from the −Z surface of the frame portion 42 to the −Z surface of the thin film portion 44 is determined by taking into consideration a maximum displacement of the movable portion 11, and is 0.1 mm to 0.4 mm, for example.

The chip 10 is disposed on the −Z side of the substrate 40. The chip 10 will be described later in more detail. The +Z surface of the frame portion 12 of the chip 10 is bonded and fixed to the −Z surface of the frame portion 42 of the substrate 40 via an adhesive layer made of a resin adhesive or the like, for example. A planar shape of the chip 10 is hexagonal. The planar shape of the chip 10 may be circular, elliptical, or polygonal, such as a triangular, rectangular, or the like.

The membrane 20 is a flexible film-like member and is disposed on the −Z side of the chip 10. The membrane 20 includes a central portion 21, a frame portion 22, and a connecting portion 24. The central portion 21 fixes the movable portion 11. The frame portion 22 surrounds the central portion 21 on the XY plane. The connecting portion 24 connects the central portion 21 and the frame portion 22. The connecting portion 24 protrudes in the −Z direction from the −Z surfaces of the frame portion 22 and the central portion 21, and is curved in the −Z direction. The connecting portion 24 has a plurality of slits 24A extending in a radial direction and disposed at predetermined intervals. Accordingly, when the central portion 21 of the membrane 20 vibrates in the Z direction, it is possible to suppress the displacement of the central portion 21 from being restricted by tensile stress from the frame portion 22.

The +Z surface of the frame portion 22 is bonded and fixed to the −Z surface of the frame portion 12 of the chip 10 via an adhesive layer made of a resin adhesive or the like, for example. A +Z surface of the central portion 21 is bonded and fixed to the −Z surface of the movable portion 11 of the chip 10 via an adhesive layer made of a resin adhesive or the like, for example. A planar shape of the membrane 20 is hexagonal. The planar shape of the membrane 20 may be a circular, elliptical, or polygonal, such as triangular, rectangular, or the like.

The membrane 20 is made of an elastomer or resin material, for example. Examples of the elastomer material include thermoplastic polyester elastomer (TPEE), thermoplastic polyurethane elastomer (TPU), or the like, for example. Examples of the resin material include polyethylene terephthalate (PET), polyimide (PI), polyether ether ketone (PEEK), or the like, for example. The membrane 20 may be a thin metal plate. A thickness of the membrane 20 is 5 μm to 50 μm, for example.

A +Z surface of the diaphragm 25 is bonded and fixed to a −Z surface of the central portion 21 via an adhesive layer made of a resin adhesive or the like, for example. The diaphragm 25 is a rigid body and is made of a material harder than the central portion 21. The vibration of the diaphragm 25 can increase the sound pressure of the sound emitted by the electroacoustic transducer 102. The diaphragm 25 may be disposed on the +Z surface of the central portion 21 of the membrane 20.

The diaphragm 25 is made of a resin, such as polyethylene naphthalate (PEN) or the like, a metal, such as aluminum or the like, or carbon. A thickness of the diaphragm 25 is 25 μm to 100 μm, for example.

The lid member 45 is disposed on the −Z side of the membrane 20. The lid member 45 can protect the membrane 20 and increase the rigidity of the electroacoustic transducer 102. In addition, when the electroacoustic transducer 102 is attached to another member, the lid member 45 can be used as an attachment reference for the electroacoustic transducer 102. The lid member 45 has an opening 45A. When viewed in the Z direction, the opening 45A overlaps the central portion 21 and the connecting portion 24. A +Z surface of the lid member 45 is bonded and fixed to the −Z surface of the frame portion 22 of the membrane 20 via an adhesive layer made of a resin adhesive or the like, for example. The lid member 45 may have one or more beams that traverse the opening 45A. The number of beams and a width of the beams are determined by taking into consideration the displacement of the movable portion 11.

The lid member 45 is a rigid body. The lid member 45 is made of a metal, such as stainless steel (SUS), aluminum, or the like, or a resin, such as polycarbonate (PC) or the like, for example. A thickness of the lid member 45 is approximately 0.1 mm, for example. The lid member 45 may be omitted.

The mesh 48 is disposed on the +Z side of the substrate 40. The mesh 48 has a large number of small apertures. By adjusting an aperture ratio of the mesh 48, a Q value of a resonance frequency of the electroacoustic transducer 102 can be reduced. Hence, a frequency response of the electroacoustic transducer 102 can be made closer to flat. In addition, it is possible to reduce a possibility of foreign substances, such as dust, water, or the like from entering inside the electroacoustic transducer 102 while maintaining the air inflow and outflow via the through hole 40A. The mesh 48 is bonded to the +Z surface of the substrate 40 via an adhesive layer 49, such as a double-sided tape having an opening at a center, for example. The mesh 48 is made of a resin, such as polyester or the like, for example. The mesh 48 may not be omitted.

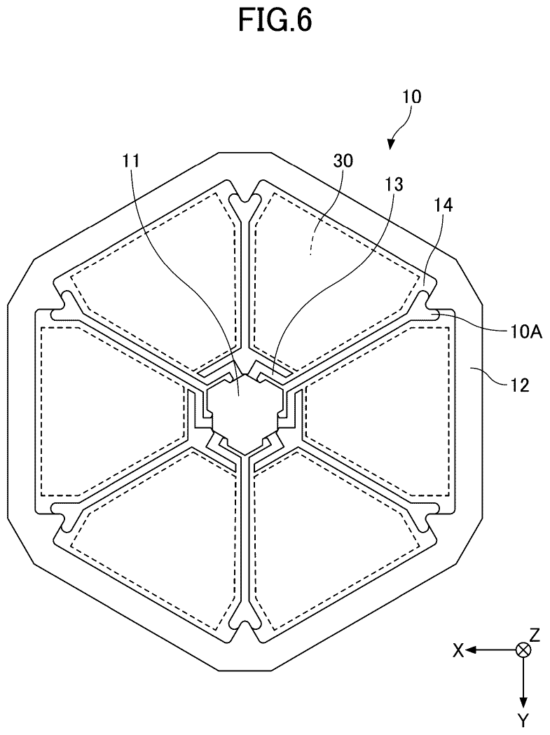

FIG. 6 is a plan view of the chip according to the second embodiment. In FIG. 6, the piezoelectric element 30 is indicated by a broken line. As illustrated in FIG. 6, the planar shape of the frame portion 12 is hexagonal. Six connecting portions 14 are provided to extend inward from six sides of an inner edge of the frame portion 12. The six connecting portions 14 are separated from one another via an opening 10A interposed between two adjacent connecting portions 14. Torsion bars 13 connect inner edges of the connecting portions 14 and the movable portion 11. The piezoelectric element 30 is disposed on the +Z surface of each connecting portion 14. A planar area of the piezoelectric element 30 is substantially the same as a planar area of the connecting portion 14. Accordingly, the connecting portions 14 can be greatly warped by applying the drive signals to the piezoelectric elements 30. The planar area of the piezoelectric element 30 is preferably 0.5 times the planar area of the connecting portion 14 or greater, for example.

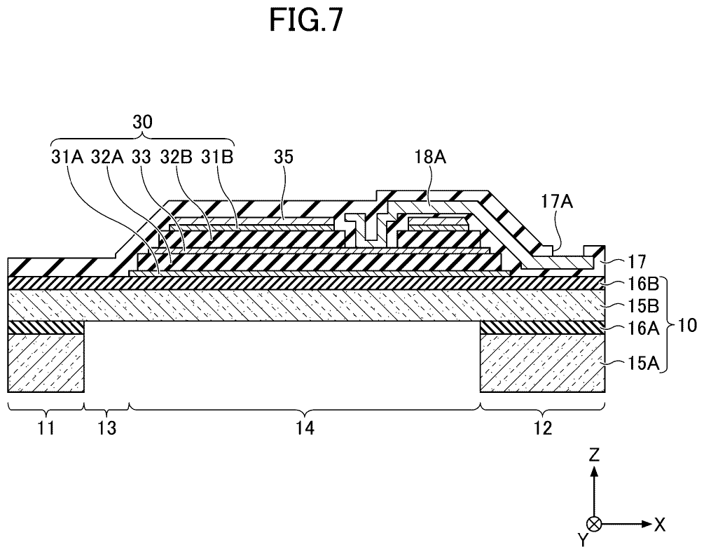

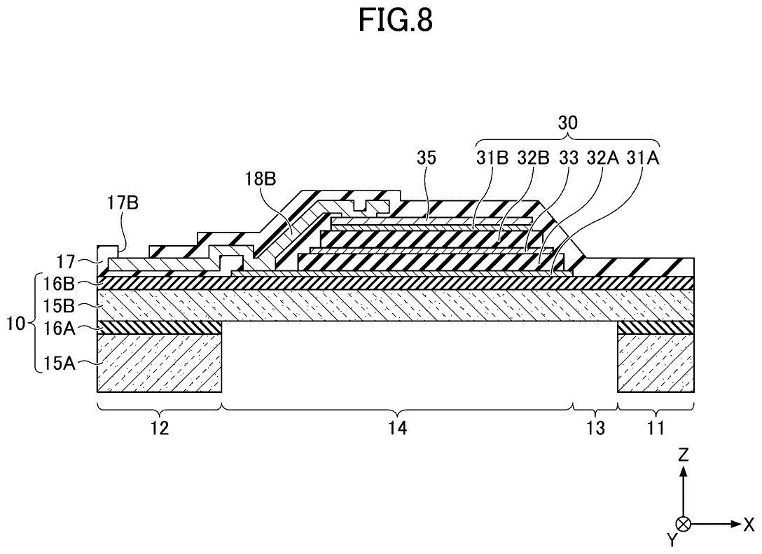

FIG. 7 and FIG. 8 are cross sectional views of the chip according to the second embodiment. FIG. 7 is a cross sectional view of a portion where interconnect 18A is routed out from electrode 33, and FIG. 8 is a cross sectional view of a portion where interconnect 18B is routed out from electrodes 31A and 31B.

As illustrated in FIG. 7 and FIG. 8, the chip 10 is a silicon on insulator (SOI) substrate, and includes a semiconductor layer 15A, an insulating layer 16A, a semiconductor layer 15B, and an insulating layer 16B that are stacked in this order in the +Z direction. The movable portion 11 and the frame portion 12 include the semiconductor layer 15A, the insulating layer 16A, the semiconductor layer 15B, and the insulating layer 16B. Thus, the movable portion 11 and the frame portion 12 constitute thick film portions. The connecting portions 14 and the torsion bars 13 include the semiconductor layer 15B and the insulating layer 16B, but do not include the semiconductor layer 15A and the insulating layer 16B. As a result, the connecting portions 14 and the torsion bars 13 constitute thin film portions thinner than the thick film portions.

Each piezoelectric element 30 includes the electrode 31A, a piezoelectric layer 32A, the electrode 33, a piezoelectric layer 32B, and an electrode 31B that are stacked in this order in the +Z direction. A polarization direction of the piezoelectric layer 32A and a polarization direction of the piezoelectric layer 32B are opposite to each other. A stress-applying film 35 is provided on the electrode 31B. The stress-applying film 35 applies stress to the chip 10.

The insulating layer 17 is provided on the insulating layer 16B so as to cover the piezoelectric element 30. The interconnects 18A and 18B are provided in the insulating layer 17. The interconnect 18A is electrically connected to the electrode 33. The interconnect 18B is electrically connected to the electrodes 31A and 31B. The insulating layer 17 has an opening 17A exposing a portion of the interconnect 18A, and an opening 17B exposing a portion of the interconnect 18B. A drive signal is applied between the interconnect 18A and the interconnect 18B via the opening 17A and the opening 17B. Thus, the drive signal is applied between the electrode 33 and the electrodes 31A and 31B. Although the piezoelectric layers 32A and 32B are two stacked layers in the example described above, the piezoelectric layer may be a single layer or three or more stacked layers.

The semiconductor layers 15A and 15B are silicon layers, for example, and the insulating layers 16A and 16B are silicon oxide layers, for example. By forming the chip 10 using the SOI substrate, the movable portion 11, the frame portion 12, the connecting portions 14, and the torsion bars 13 can be finely formed using semiconductor manufacturing processes. The chip 10 may be formed using an insulating substrate other than the SOI substrate. Examples of the insulating substrate include a sapphire substrate, an alumina substrate, a spinel substrate, a quartz substrate, a crystal substrate, a glass substrate, a ceramic substrate, or the like.

The piezoelectric layers 32A and 32B are piezoelectric bodies having the perovskite crystal structure as the piezoelectric layer 32, for example. Examples of the piezoelectric body having the perovskite crystal structure include lead zirconate titanate (PZT), lead niobium-doped zirconate titanate (PNZT), lead lanthanum zirconate titanate (PLZT), lead lanthanum titanate (PLT), lead magnesium niobate (PMN), PMNN (lead manganese niobate (PMNN), and barium titanate (BaTiO₃), for example. The electrodes 31A, 31B, and 33 and the interconnects 18A and 18B are metal layers, such as gold layers, copper layers, platinum layers, aluminum layers, alloy layers added with silicon to aluminum, alloy layers added with silicon and copper to aluminum, or the like, for example. The insulating layer 17 is a silicon oxide layer or a silicon nitride layer, for example.

The stress-applying film 35 is a film having tensile stress, and is a metal film, such as a titanium tungsten film, a copper film, a titanium film, a gold film, a silver film, or the like, or an insulating film, such as a silicon nitride film or the like, for example. When the stress-applying film 35 is formed by heating the chip 10 in a case where a coefficient of thermal expansion of the stress-applying film 35 is larger than a coefficient of thermal expansion of the chip 10, and the stress-applying film 35 has tensile stress at room temperature due to thermal stress. In addition, in a case where the stress-applying film 35 is formed by sputtering, a noble gas, such as argon gas or the like, is used as a sputtering gas. When the stress-applying film 35 is formed, an element of an atmospheric gas, such as argon gas or the like, is absorbed by the stress-applying film 35. Thereafter, when the element of the atmospheric gas is released from the stress-applying film 35, the stress-applying film 35 is caused to have tensile stress. As described above, the stress of the stress-applying film 35 can be set to the tensile stress or compressive stress depending on the material used for the stress-applying film 35, film forming conditions of the stress-applying film 35, or the like.

Sample A and sample B were manufactured as samples of the second embodiment. In the samples A and B, a titanium tungsten film was used for the stress-applying film 35. The titanium tungsten film is confirmed to have tensile stress. Table 1 illustrates the thickness of the stress-applying film 35, the thickness of the semiconductor layer 15B, total harmonic distortions (THDs), and sound pressure levels (SPLs) of each of the samples A and B.

TABLE 1

| | THICKNESS | THICKNESS | | | | |
|---|---|---|---|---|---|---|
| | OF STRESS- | OF SEMICON- | | | | |
| | APPLYING | DUCTOR | THD | THD | SPL | SPL |
| SAMPLE | FILM 35 | LAYER 15B | @20 Hz | @1000 Hz | @20 Hz | @1000 Hz |
| A | 300 nm | 15 μm | 26.1% | 20.1% | 130.3 dB | 119.6 dB |
| B | 500 nm | 25 μm | 13.5% | 19.4% | 132.6 dB | 124.7 dB |

As illustrated in Table 1, in the sample A, the thickness of the stress-applying film 35 is 300 nm, and the thickness of the semiconductor layer 15B is 15 μm. In the sample B, the thickness of the stress-applying film 35 is 500 nm, and the thickness of the semiconductor layer 15B is 25 μm.

A ground potential was supplied to the electrodes 31A and 31B, a DC voltage was applied to the electrode 33, and the displacements of the movable portion 11 and the diaphragm 25 were measured. The displacement in the +Z direction was regarded as being positive.

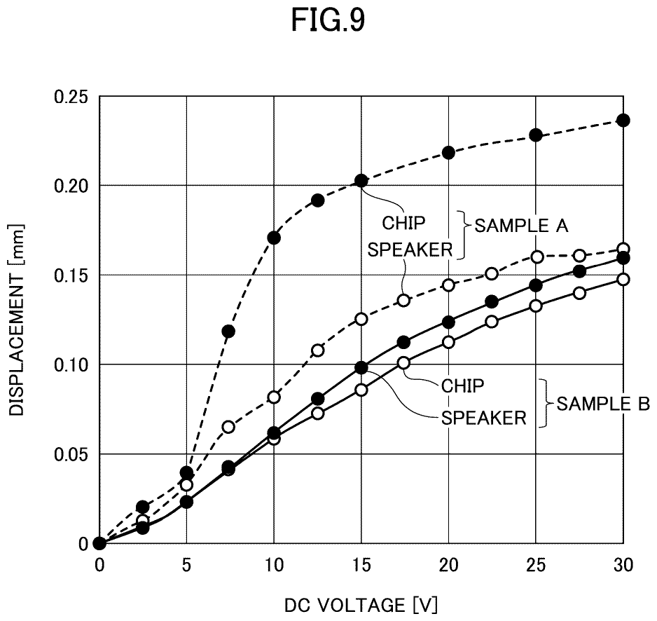

FIG. 9 is a diagram illustrating the displacement with respect to the DC voltage in the samples A and B of the second embodiment. The displacement when the voltage is 0 V is assumed to be 0 mm. In FIG. 9, “CHIP” indicates the displacement of the movable portion 11 in the chip 10, and “SPEAKER” indicates the displacement of the diaphragm 25 in the electroacoustic transducer 102.

As illustrated in FIG. 9, in “CHIP” of the sample A, the displacement saturates when the voltage is 15 V or higher. For example, the displacement is approximately 0.2 mm when the voltage is 0 V to 15 V, whereas the displacement is approximately 0.04 mm when the voltage is 15 V to 30 V. In “SPEAKER” of the sample A, the displacement is somewhat saturated when the voltage is 15 V or higher. As described above, in the sample A, the linearity of the displacement with respect to the voltage is poor for both “CHIP” and “SPEAKER”.

In “CHIP” of the sample B, the saturation of the displacement at the voltage of 15 V or higher is significantly improved compared to “CHIP” of the sample A. In “SPEAKER” of the sample B, the saturation of the displacement at the voltage of 15 V or higher is improved compared to “SPEAKER” of the sample A. As described above, in the sample B, the linearity of the displacement with respect to the voltage is improved for both “CHIP” and “SPEAKER” when compared to the sample A.

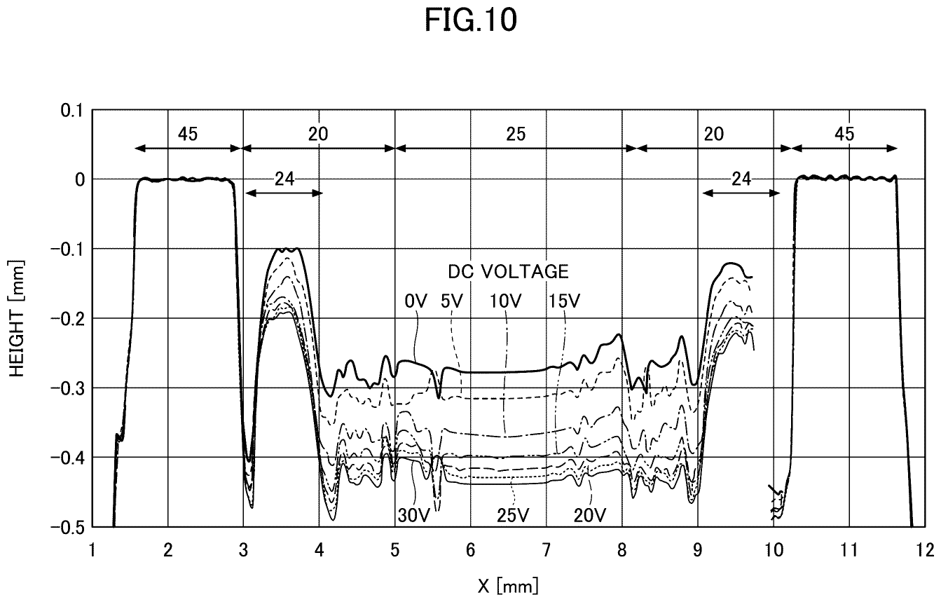

FIG. 10 is a diagram illustrating a height with respect to a position X of the sample A of the second embodiment. In FIG. 10, X on the abscissa indicates a position in the X direction in FIG. 6, and Z on the ordinate indicates the height when the −Z surface of the lid member 45 in FIG. 5 is assumed to be 0 when the DC voltage is applied. The lid member 45, the membrane 20, and the diaphragm 25 indicated by horizontal arrows indicate the members on the surface that are farthest in the −Z direction at the position X. In the lid member 45, the ordinate indicates the height of the position of the −Z surface of the lid member 45. In the membrane 20 and the diaphragm 25, the ordinate indicates the height of the position of the −Z surface of the membrane 20 and the diaphragm 25, respectively.

As illustrated in FIG. 10, the −Z surface of the lid member 45 does not move even when the DC voltage is applied. The −Z surface of the diaphragm 25 moves in the +Z direction when the DC voltage is applied, thereby increasing the height of the diaphragm 25 in the negative direction. However, when the DC voltage becomes 15 V or higher, the displacement of the height of the diaphragm 25 becomes small.

In the membrane 20, when the DC voltage is 15 V or higher, the displacement of the height of the diaphragm 25 becomes small. In particular, when the DC voltage is 15 V or higher, the change in height of the curved connecting portion 24 is smaller than the change in height of the diaphragm 25. It may be regarded that when the DC voltage is 15 V or higher, the curved connecting portion 24 is fully extended to inhibit the displacement of the diaphragm 25.

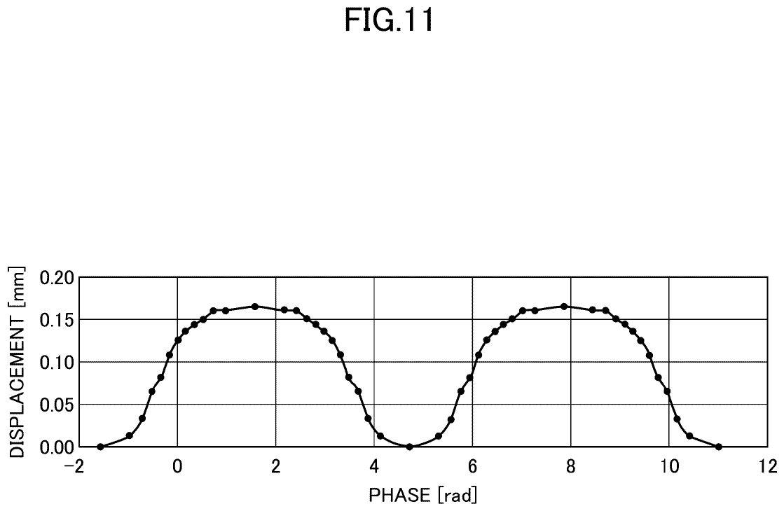

FIG. 11 is a diagram illustrating the displacement with respect to a phase in the sample A of the second embodiment. From the relationship between the DC voltage and the displacement in “SPEAKER” of the sample A in FIG. 9, the relationship between the phase and the displacement when the drive signal is a trigonometric wave (sine wave) is illustrated by a graph. It is assumed that the bias voltage Vbias of the drive signal is 15 V, and the minimum and maximum values of the drive signal are 0 V and 30 V, respectively. In FIG. 10, the abscissa indicates the phase in radians, and the ordinate indicates the calculated displacement. The relationship between the phase and the displacement is distorted from a trigonometric wave.

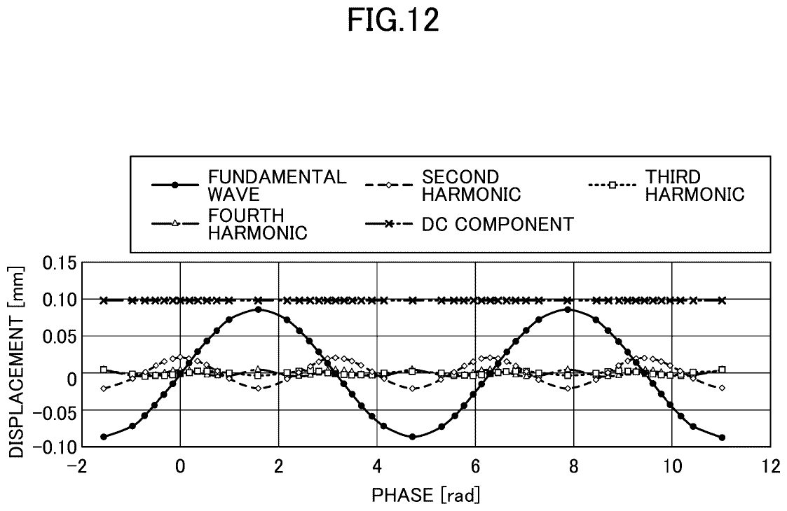

FIG. 12 is a diagram illustrating the displacement with respect to the phase in the sample A of the second embodiment. A Fourier expansion up to fourth harmonic is performed on the relationship between the phase and the displacement in FIG. 11. As illustrated in FIG. 12, an amplitude of a fundamental wave is the largest, but the amplitude of the second harmonic is also large. Although the amplitude of the third harmonic is small, the amplitude of the fourth harmonic is larger than the amplitude of the third harmonic. Thus, even-order harmonic components are large. The THD is calculated using values up to the fourth harmonic is 25%.

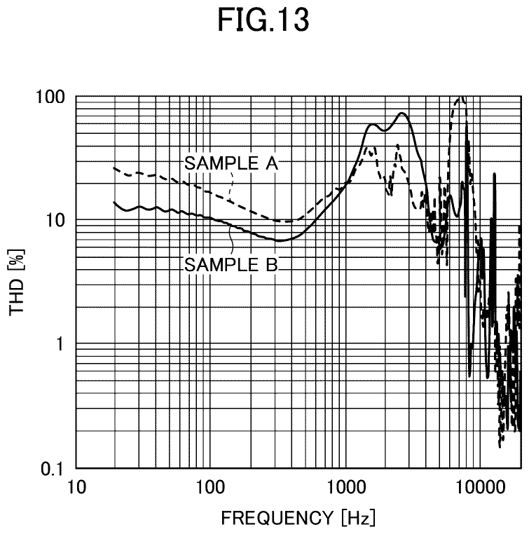

FIG. 13 is a diagram illustrating the THD with respect to the frequency of the samples A and B of the second embodiment. It is assumed that the bias voltage Vbias of the drive signal is 15 V, and the minimum and maximum values of the drive signal are 0 V and 30 V, respectively. As illustrated in FIG. 13, the THD of the sample B is smaller than that of the sample A ate 1000 Hz or lower. As illustrated in Table 1, in the sample A, the THD at 20 Hz is 26.1%, and the THD at 1000 Hz is 20.1%. These value are substantially the same as the value of 25% for the THD calculated in FIG. 12. In contrast, in the sample B, the THD at the 20 Hz is 13.5%, and the THD at 1000 Hz is 19.4%, which are improved compared to the THD values of the sample A. As described above, the harmonic component is smaller in the sample B than in the sample A. It may be regarded that the harmonic component is smaller in the sample B because the linearity of the sample B is improved compared to the sample A as illustrated in FIG. 9.

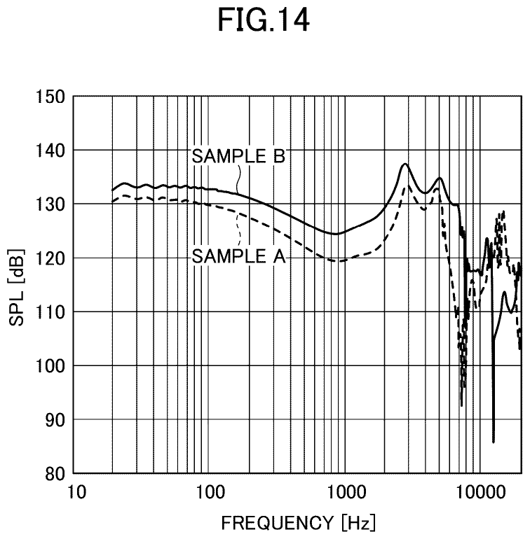

FIG. 14 is a diagram illustrating the SPL with respect to the frequency in samples A and B of the second embodiment. As illustrated in FIG. 14, the SPL of the sample B is larger than that of the sample A at 5000 Hz or lower. As illustrated in Table 1, the SPL at 20 Hz is 130.3 dB and the SPL at 1000 Hz is 119.6 dB in the sample A, whereas the SPL at 20 Hz is 132.6 dB and the SPL at 1000 Hz is 124.7 dB in the sample B, which are improved compared to the SPL values of the sample A. As described above, the sound pressure level of the sample B is higher than that of the sample A. In FIG. 9, although the sample A has a larger displacement than the sample B, the sample A has a smaller SPL than the sample B as illustrated in FIG. 14. It may be regarded that the sample A has the smaller SPL because the SPL is related to not only the displacement but also to the linearity.

It may be regarded that the reason why the linearity is improved in the sample B as illustrated in FIG. 9 and the THD and the SPL of the sample B are improved as illustrated in FIG. 13 and FIG. 14 is because, in the sample B, the stress-applying film 35 having tensile stress is made thick, and thus, in the state where no drive signal is applied, the chip 10 warps in the −Z direction and the movable portion 11 is located in the −Z direction as illustrated in FIG. 4A. As a result, the chip 10 is brought into a state close to a flat state at the bias voltage Vbias as illustrated in FIG. 4B. Hence, as illustrated in FIG. 9, it may be regarded that the linearity of the displacement with respect to the voltage improves.

As illustrated in FIG. 4A of the first embodiment, in order to arrange the position P1 of the movable portion 11 in the second direction 62 with respect to the flat state when the drive signal is not applied to the piezoelectric element 30, the stress-applying film 35 having tensile stress may be provided on the +Z side of the piezoelectric element 30 as in the second embodiment. The stress-applying film 35 having compressive stress may be provided on the −Z side of the connecting portion 14.

The stress-applying film 35 for applying tensile stress is provided on the +Z side of a neutral plane of a multilayer film (the semiconductor layer 15B, the insulating layer 16B, the piezoelectric element 30, and the insulating layer 17 in FIG. 7 and FIG. 8) in which the piezoelectric element 30 is provided in the connecting portion 14. Alternatively, the stress-applying film 35 for applying compressive stress is provided on the −Z side of the neutral plane of the multilayer film. Accordingly, as illustrated in FIG. 4A, the position P1 of the movable portion 11 can be arranged in the second direction 62 with respect to the flat state. The neutral plane is a plane that neither expands nor contracts in the multilayer film.

As described above, the stress-applying film 35 is stacked on the piezoelectric element 30 and need only have stress that causes the movable portion 11 to warp in the second direction 62 with respect to the frame portion 12. The stress is a sum of internal stress and thermal stress.

As illustrated in FIG. 5, the membrane 20 includes the central portion 21 that fixes the movable portion 11, the frame portion 22 (second frame portion) that surrounds the central portion 21, and the connecting portion 24 (second connecting portion) that connects the central portion 21 and the frame portion 22 and has flexibility. Accordingly, the sound pressure can be improved by the central portion 21 or the diaphragm 25.

The connecting portion 14 is curved from the chip 10 toward the −Z direction (second direction) where the membrane 20 is located. Hence, it is possible to prevent the connecting portion 24 from restricting the movement of the central portion 21 or the diaphragm 25.

### Third Embodiment

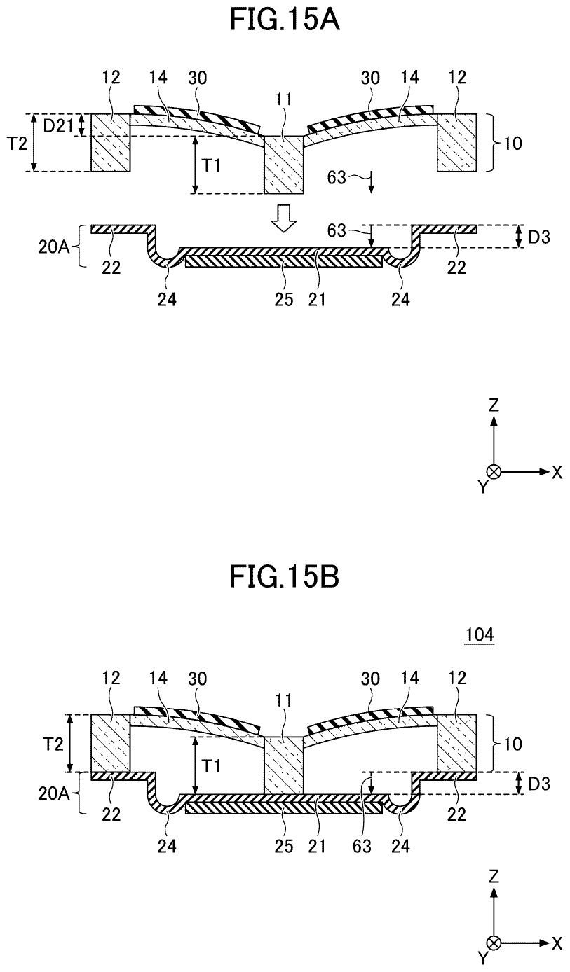

A third embodiment is an example in which the shape of the membrane or the shape of the chip is changed from that of the second embodiment. FIG. 15A and FIG. 15B are cross sectional views of the electroacoustic transducer according to the third embodiment. FIG. 15A is a cross sectional view illustrating a chip 10 and a membrane 20A in the third embodiment.

As illustrated in FIG. 15A, in a state where no drive signal is applied to the chip 10, the movable portion 11 is located in the −Z direction from the flat state, and the displacement D21 is negative. Because a thickness T1 of the movable portion 11 and a thickness T2 of the frame portion 12 are identical, displacements of the −Z surface of the movable portion 11 and the −Z surface of the frame portion 12 are D21.

In a free state where no force is applied to the membrane 20A, the central portion 21 of the membrane 20A is located in a third direction 63 with respect to the frame portion 22. The +Z surface of the central portion 21 and the +Z surface of the frame portion 22 are spaced apart from each other by a distance D3. An absolute value of the displacement D21 and the distance D3 are substantially the same. In this state, the chip 10 is bonded to the membrane 20A.

As illustrated in FIG. 15B, in the electroacoustic transducer 104 according to the third embodiment, the membrane 20A is provided on the −Z side of the chip 10. The +Z surface of the frame portion 22 of the membrane 20A is bonded and fixed to the −Z surface of the frame portion 12 of the chip 10. The +Z surface of the central portion 21 of the membrane 20A is bonded and fixed to the −Z surface of the movable portion 11 of the chip 10.

A chip with a negative D21 was manufactured as the chip 10 of FIG. 15A. An electroacoustic transducer in which the chip 10 is bonded to the membrane 20 having no step and D3=0 mm, and the electroacoustic transducer 104 according to the third embodiment in which the manufactured chip 10 is bonded to the membrane 20A having the step and D3=0.4 mm were manufactured. Although |D21|=D3 is preferable, D3>|D21| stands in the present experiment. The structure is otherwise the same as that of the sample B of the second embodiment.

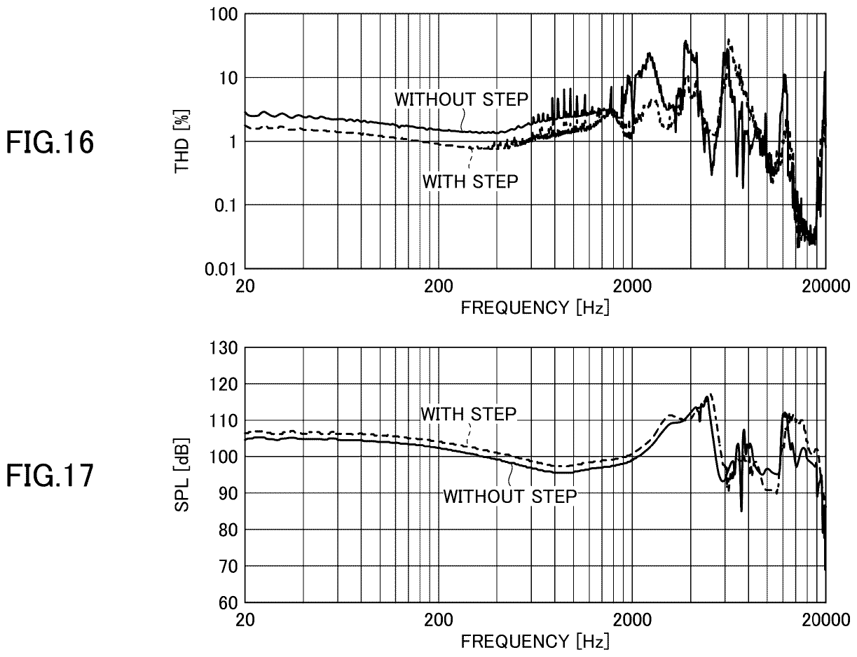

FIG. 16 is a graph illustrating the THD with respect to the frequency in a membrane without a step and a membrane with a step. As illustrated in FIG. 16, the membrane having the step has a smaller THD than the membrane having no step at the 1500 Hz or lower. Thus, the membrane having the step has a smaller harmonic component than the membrane having no step.

FIG. 17 is a diagram illustrating the SPL with respect to the frequency in the membrane without the step and the membrane with the step. As illustrated in FIG. 17, the SPL of the membrane having the step is larger than that of the membrane having no step at 3000 Hz or lower. Thus, the membrane having the step has a higher sound pressure than the membrane having no step.

A process of bonding the chip 10 and the membrane 20A during the manufacturing process of the electroacoustic transducer 104 will be described. When the chip 10 is formed from a substrate, such as the SOI substrate or the like, the thickness T1 of the movable portion 11 and the thickness T2 of the frame portion 12 are identical. As illustrated in FIG. 15A, when no drive signal is applied, the movable portion 11 is located in the −Z direction from the frame portion 12 in the chip 10. When the chip 10 is bonded to the membrane 20 having no step such that D3=0 mm, a DC voltage for making the chip 10 flat is applied to the piezoelectric element 30 so that the chip 10 assumes the flat state. The chip 10 and the membrane 20 are bonded to each other in the flat state of the chip 10. Accordingly, the DC voltage is applied to the piezoelectric element 30 in the process of bonding the chip 10 and the membrane 20. In a case where the chip 10 illustrated in FIG. 15A is bonded to the membrane 20 having no step without applying the DC voltage, a lower surface of the movable portion 11 of the chip 10 is pressed against an upper surface of the central portion 21 using a suitable jig to make the chip 10 assume the flat state. In this state, a lower surface of the frame portion 12 may be bonded to an upper surface of the frame portion 22.

In the membrane 20A having the step, the step with the distance D3 is generated even when a DC voltage is not applied to the piezoelectric element 30. For this reason, the chip 10 and the membrane 20A can be bonded without applying the DC voltage to the piezoelectric element 30. In addition, the chip 10 and the membrane 20A can be bonded without using a special jig. Hence, the manufacturing processes can be simplified. When the chip 10 illustrated in FIG. 15A is bonded to the membrane 20 having no step, a force causing the chip 10 to return to the flat state is applied from the membrane 20 when no voltage is applied. In the membrane 20A having the step, it is possible to reduce the force from the membrane 20A that causes the chip 10 to return to the flat state.

The state where the thickness T1 and the thickness T2 are identical tolerates manufacturing errors. For example, a difference between the thicknesses T1 and T2 is within a range of +0.01 mm.

Further, as illustrated in FIG. 16, by using the membrane 20A having the step as the membrane to which the chip 10 is bonded, the linearity can be improved compared to the case where the membrane 20 having no step is used.

The distance D3 is preferably close to the displacement D21 in the second direction 62 between the +Z surface of the movable portion 11 and the +Z surface of the frame portion 12 when the drive signal is not applied in FIG. 4A. For example, the distance D3 is preferably 0.5 times the displacement D21 or greater and 1.5 times the displacement D21 or less, and more preferably 0.8 times the displacement D21 or greater and 1.2 times the displacement D21 or less. The distance D3 satisfying such ranges can improve the linearity and also simplify the manufacturing processes.

### <First Modification of Third Embodiment>

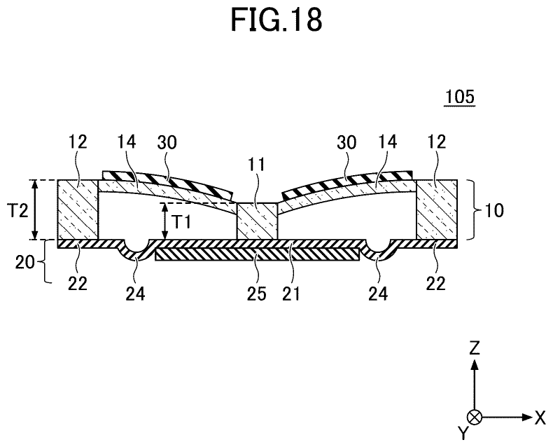

FIG. 18 is a cross sectional view of the electroacoustic transducer according to a first modification of the third embodiment. As illustrated in FIG. 18, in an electroacoustic transducer 106 according to the first modification of the third embodiment, the membrane 20 has no step in the free state where no force is applied. The thickness T1 of the movable portion 11 is smaller than the thickness T2 of the frame portion 12. Accordingly, the chip 10 and the membrane 20 can be bonded to each other without applying a DC voltage to the piezoelectric element 30 for making the chip 10 flat. Thus, the manufacturing processes can be simplified.

A thickness corresponding to a difference T2-T1 of the thicknesses T1 and T2 is preferably close to the displacement D21 in the second direction 62 between the +Z surface of the movable portion 11 and the +Z surface of the frame portion 12 when the drive signal is not applied. For example, the thickness corresponding to the difference T2-T1 is preferably 0.5 times the displacement D21 or greater and 1.5 times the displacement D21 or less, and more preferably 0.8 times the displacement D21 or greater and 1.2 times the displacement D21 or less. In this case, it is possible to simplify the manufacturing processes.

### <Second Modification of Third Embodiment>

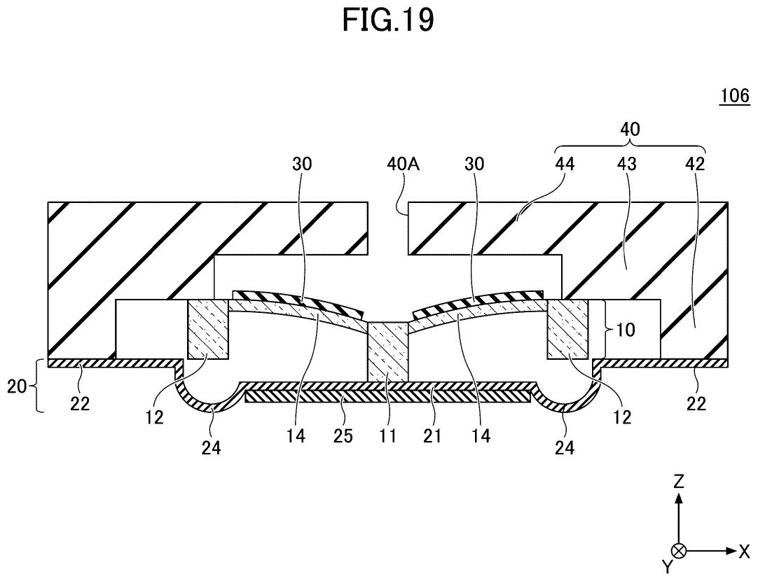

FIG. 19 is a cross sectional view of the electroacoustic transducer according to a second modification of the third embodiment. As illustrated in FIG. 19, in the electroacoustic transducer 106 according to the second modification of the third embodiment, the frame portion 12 of the chip 10 and the frame portion 22 of the membrane 20 are not bonded to each other. The substrate 40 has a step portion 43 between the frame portion 42 and the thin film portion 44. A-Z surface of the step portion 43 is located between the −Z surface of the frame portion 42 and the −Z surface of the thin film portion 44 along the Z direction.

The −Z surface of the frame portion 42 of the substrate 40 is bonded to the +Z surface of the frame portion 22 of the membrane 20. The −Z surface of the step portion 43 of the substrate 40 is bonded to the +Z surface of the frame portion 12 of the chip 10. Accordingly, the frame portion 12 of the chip 10 is fixed to the frame portion 22 of the membrane 20 with the substrate 40 interposed therebetween. In other words, the substrate 40 fixes the frame bodies 12 and 22 together.

When viewed in the Z direction, the frame portion 22 of the membrane 20 is located on an outer side of the frame portion 12 of the chip 10. This arrangement enables the areas of the central portion 21 of the membrane 20 and the diaphragm 25 to be increased. Hence, the sound pressure can be increased. The area of the central portion 21 or the diaphragm 25 in the plan view is preferably 0.5 times the area of the region of the chip 10 on the inner side of the frame portion 12 in the plan view (region including the movable portion 11 and the connecting portion 14) or greater.

The frame portion 12 overlaps the connecting portion 24 when viewed in the Z direction. This arrangement enables the areas of the central portion 21 of the membrane 20 and the diaphragm 25 to be increased. Accordingly, the sound pressure can be increased. Further, even when the central portion 21 vibrates, the central portion 21 can be prevented from coming into contact with the frame portion 12.

### Fourth Embodiment

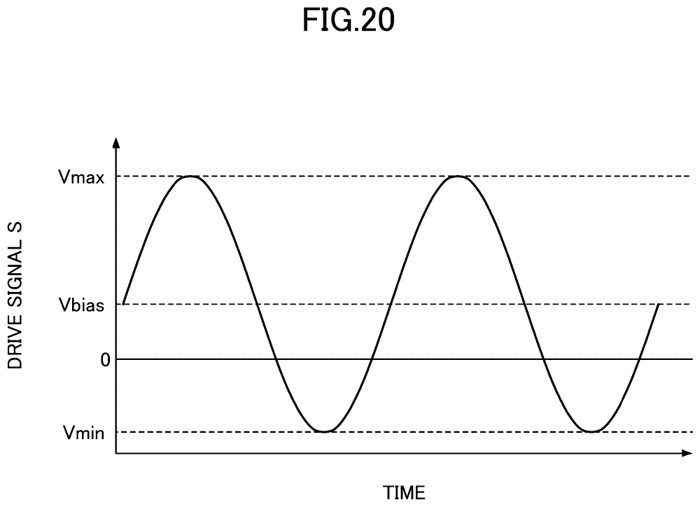

A fourth embodiment is an example in which the bias voltage Vbias is varied from those of the second embodiment, the third embodiment, and the modifications of the third embodiment. FIG. 20 is a schematic diagram illustrating the drive signal S with respect to the time in the fourth embodiment. As illustrated in FIG. 20, the minimum value Vmin of the drive signal S is negative. By making the bias voltage Vbias closer to the 0 V than in FIG. 2, the chip 10 can be made closer to the flat state as illustrated in FIG. 4B. Thus, the linearity can be improved. The bias voltage Vbias is a voltage that does not induce depolarization of the piezoelectric layer 32 when the drive signal is the minimum value Vmin. When the movable portion 11 of the chip 10 is positioned in the second direction 62 with respect to the frame portion 12 as illustrated in FIG. 4A when the drive signal S is 0 V, the minimum value Vmin may be larger than 0 V.

Using a sample having the same structure as the sample A of the second embodiment, the THD and the SPL were measured for the bias voltages Vbias of 15 V and 9 V and the drive signal having the amplitude of 30 V.

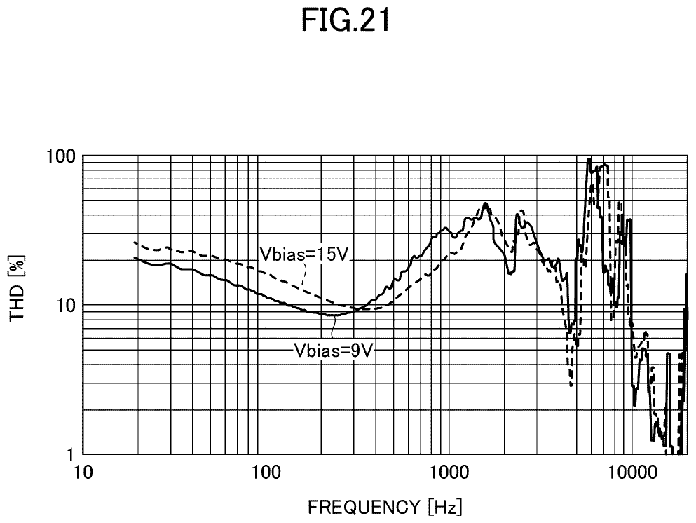

FIG. 21 is a diagram illustrating THD with respect to the frequency of samples with varied bias voltages. As illustrated in FIG. 21, at frequencies of 300 Hz or lower, the THD at Vbias=9 V is lower than the THD at Vbias=15. As described above, the harmonic components are smaller at Vbias=9 V than at Vbias=15 V.

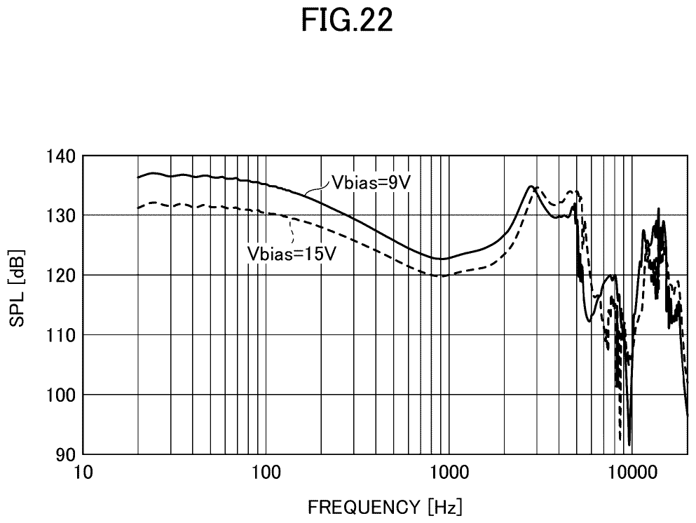

FIG. 22 is a diagram illustrating the SPL with respect to the frequency of the samples with the varied bias voltages. As illustrated in FIG. 22, at frequencies of 2500 Hz or lower, the SPL at Vbias=9 V is higher than the SPL at Vbias=15 V. As described above, the acoustic pressure is higher at Vbias=9 V than at Vbias=15 V.

When Vbias=9 V, the chip 10 can be brought into a state close to the flat state as illustrated in FIG. 4B. Hence, the linearity can be improved. For this reason, it is possible to improve harmonic characteristics and the sound pressure.

Similar to FIG. 4A, FIG. 4B, and FIG. 4C, the displacement D20 of the movable portion 11 in the first direction 61 from the flat state when the bias voltage Vbias is applied to the piezoelectric elements 30 is preferably −0.25×|D22−D21| or greater and +0.25×|D22−D21| or less, more preferably −0.15×|D22−D21| or greater and +0.15×|D22−D21| or less, and even more preferably −0.1×|D22−D21| or greater and +0.1×|D22−D21| or less.

In the electroacoustic transducer 102 including the stress-applying film 35 as in the second embodiment, the bias voltage Vbias illustrated in FIG. 20 may be applied to the piezoelectric element 30. In addition, the bias voltage Vbias illustrated in FIG. 20 may be applied to the electroacoustic transducers 104 and 106 of the third embodiment and the modifications thereof. When the movable portion 11 of the chip 10 is positioned in the second direction 62 with respect to the frame portion 12 as illustrated in FIG. 4A when the drive signal S is 0 V, the bias voltage Vbias may be applied so that the minimum value Vmin becomes larger than 0 V.

### Fifth Embodiment

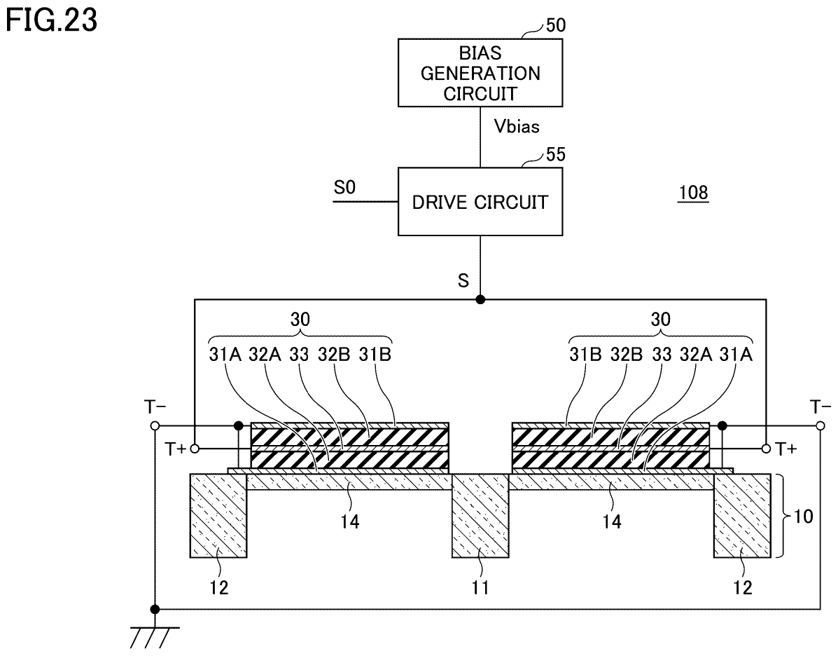

A fifth embodiment is an example in which the bias voltage Vbias is adjustable in the second through fourth embodiments. FIG. 23 is a diagram illustrating the acoustic conversion device according to the fifth embodiment. As illustrated in FIG. 23, an electroacoustic transducer 108 includes the chip 10, the piezoelectric element 30, a bias generation circuit 50, and a drive circuit 55.

As illustrated in FIG. 23, the piezoelectric element 30 is provided on the connecting portion 14 of the chip 10. In the piezoelectric element 30, the electrode 31A, the piezoelectric layer 32A, the electrode 33, the piezoelectric layer 32B, and the electrode 31B are stacked in this order on the chip 10. The electrodes 31A and 31B are grounded in common via a terminal T−. The bias generation circuit 50 generates the bias voltage Vbias. The drive circuit 55 superimposes an acoustic signal S0 on the bias voltage Vbias to generate the drive signal S. The drive signal S is supplied to the electrode 33 via a terminal T+.

### <First Example of Bias Generation Circuit>

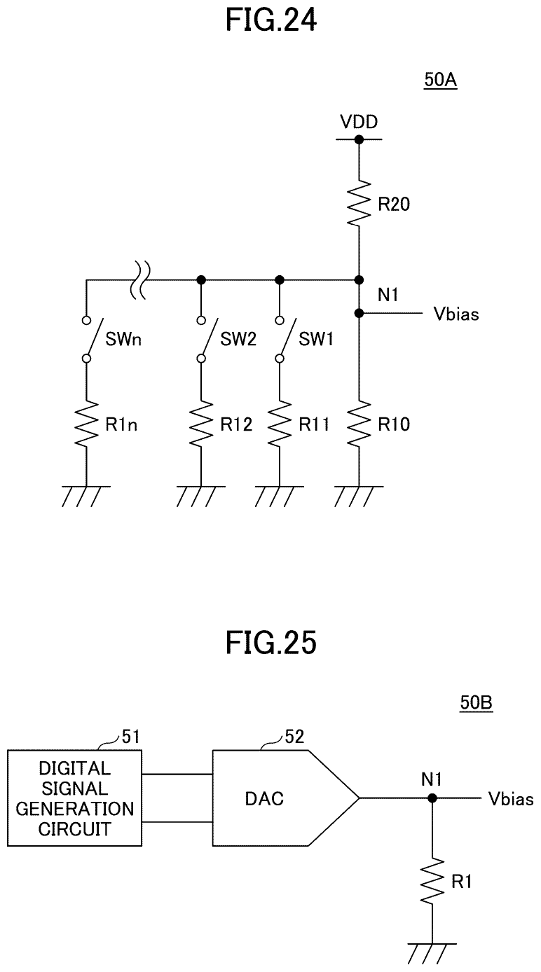

FIG. 24 is a circuit diagram illustrating a first example of the bias generation circuit according to the fifth embodiment. As illustrated in FIG. 24, a bias generation circuit 50A includes resistors R10, R11, R12 through R1n, and R20, and switches SW1, and SW2 through SWn. The resistors R10 and R20 are connected in series between a power supply voltage VDD (or a reference voltage) and a ground potential. A node N1 connects the resistors R10 and R20, and the bias voltage Vbias is generated at the node N1. The resistors R10, R11, and R12 through R1n are connected in parallel between the node N1 and the ground potential. The switches SW1 and SW2 through SWn are connected in series with the resistors R11, and R12 through R1n, respectively, between the node N1 and the ground potential. The voltage value of the bias voltage Vbias can be adjusted by varying on and off combinations of the switches SW1 and SW2 through SWn. The number of the resistors R11 through R1n and the number of the switches SW1 through SWn are one or more, and can be set as appropriate. Resistance values of the resistors R11 through R1n can be set as appropriate.

### <Second Example of Bias Generation Circuit>

FIG. 25 is a circuit diagram illustrating a second example of the bias generation circuit according to the fifth embodiment. As illustrated in FIG. 25, a bias generation circuit 50B includes a digital signal generation circuit 51, a digital-to-analog converter (DAC) 52, and a resistor R1. The digital signal generation circuit 51 generates a digital signal corresponding to a desired bias voltage Vbias. The DAC 52 converts the digital signal into the bias voltage Vbias which is an analog signal, and outputs the bias voltage Vbias to the node N1. The resistor R1 constitutes a terminating resistor connected between the ground potential and the node N1. The resistor R1 may be omitted. The digital signal generation circuit 51 generates a desired digital signal to generate the desired bias voltage Vbias.

### <First Example of Drive Circuit>

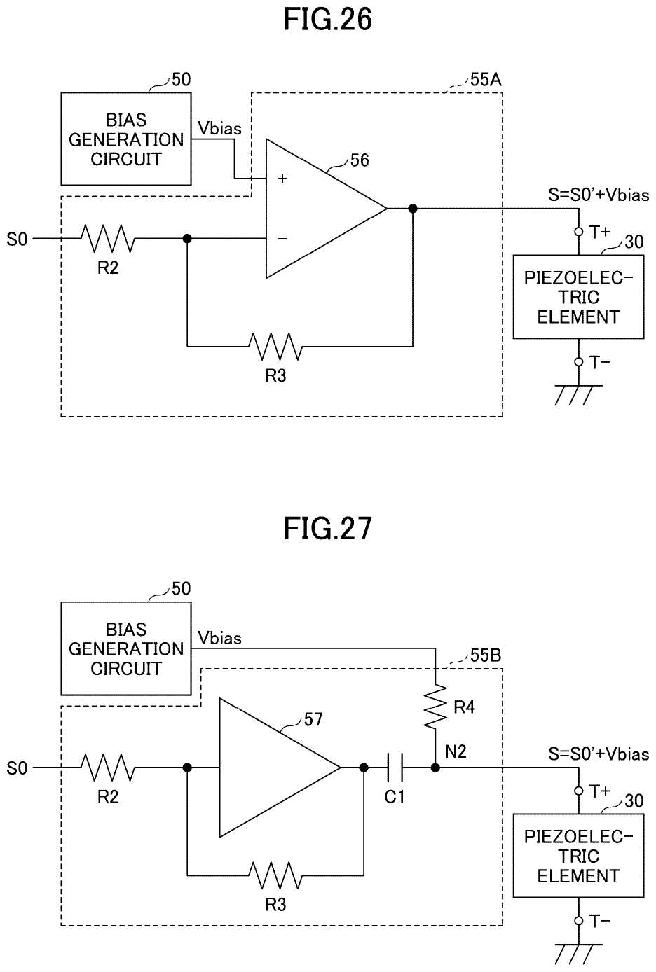

FIG. 26 is a circuit diagram illustrating a first example of the drive circuit according to the fifth embodiment. As illustrated in FIG. 26, a drive circuit 55A includes a differential amplifier 56, a resistor R2, and a resistor R3. The differential amplifier 56 has a positive input terminal, a negative input terminal, and an output terminal. The bias generation circuit 50 outputs the bias voltage Vbias to the positive input terminal of the differential amplifier 56. The acoustic signal S0 is input to the negative input terminal of the differential amplifier 56 via the resistor R2. The resistor R3 constitutes a feedback resistor connected between the negative input terminal and the output terminal of the differential amplifier 56. The drive circuit 55A inverts and amplifies the acoustic signal S0 centered on the bias voltage Vbias, and outputs the drive signal S represented by S=S0′+Vbias. The terminal T− of the piezoelectric element 30 is connected to the ground potential, and the terminal T+ of the piezoelectric element 30 is connected to the output terminal of the differential amplifier 56. Accordingly, the drive signal S is applied to the piezoelectric element 30. In the drive circuit 55A, the drive signal S is obtained by amplifying the acoustic signal S0 centered on the bias voltage Vbias.

### <Second Example of Drive Circuit>

FIG. 27 is a circuit diagram illustrating a second example of the drive circuit according to the fifth embodiment. As illustrated in FIG. 27, a drive circuit 55B includes an amplifier 57, resistors R2 through R4, and a capacitor C1. The amplifier 57 has an input terminal and an output terminal. The acoustic signal S0 is input to the input terminal of the amplifier 57 via the resistor R2. The resistor R3 constitutes a feedback resistor connected between the input terminal and the output terminal of the amplifier 57. The amplifier 57 is connected to a node N2 via the capacitor C1. The capacitor C1 is a DC-blocking capacitor. The amplifier 57 amplifies the acoustic signal S0 and outputs the amplified acoustic signal to the node N2. The bias generation circuit 50 outputs the bias voltage Vbias to the node N2 via the resistor R4. A resistance value of the resistor R4 is sufficiently low with respect to the impedance of the piezoelectric element 30. As a result, the bias voltage at the node N2 becomes Vbias. The drive signal S represented by S=S0′+Vbias is obtained by amplifying the signal S0′ that is obtained by amplifying the acoustic signal S0 centered on the bias voltage Vbias. Otherwise, the configuration of the drive circuit 55B is the same as that of the drive circuit 55A.

### <Third Example of Drive Circuit>

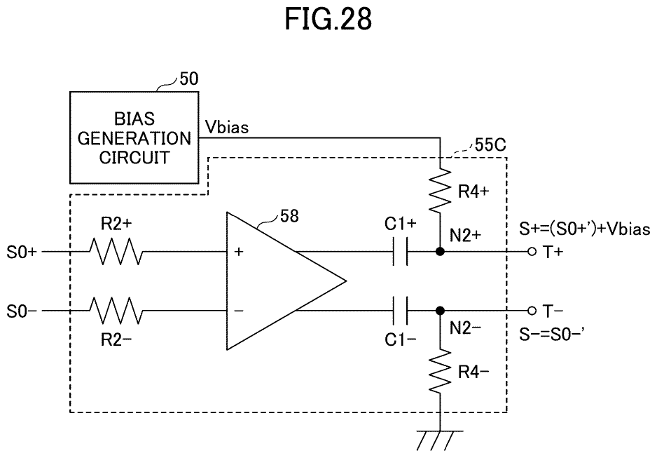

FIG. 28 is a circuit diagram illustrating a third example of the drive circuit according to the fifth embodiment. As illustrated in FIG. 28, a drive circuit 55C includes a differential amplifier 58, resistors R2+, R2−, R4+, and R4−, and capacitors C1+ and C1−. The differential amplifier 58 has a positive input terminal, a negative input terminal, a positive output terminal, and a negative output terminal. The acoustic signal S0 is input to the positive input terminal of the differential amplifier 58 via the resistor R2+. The acoustic signal S0 is input to the negative input terminal of the differential amplifier 58 via the resistor R2−. The positive input terminal of the differential amplifier 58 is connected to a node N2+ via the capacitor C1+. The negative input terminal of the differential amplifier 58 is connected to a node N2− via the capacitor C1−. The capacitors C1+ and C1− are DC blocking capacitors. The differential amplifier 58 differentially amplifies the acoustic signals S0+ and S0−, and outputs drive signals S+ and S−, which are amplified differential signals, to the nodes N2+ and N2−, respectively.

The bias generation circuit 50 outputs the bias voltage Vbias to the node N2+via the resistor R4+. The ground potential is supplied to the node N2− via the resistor R4−. Resistance values of the resistors R4+ and R4− are sufficiently low with respect to the impedance of the piezoelectric element 30. As a result, the bias voltages at the nodes N2+ and N2− become Vbias and 0 V, respectively. The nodes N2+ and N2− are electrically connected to the terminals T+ and T− of the piezoelectric element 30, respectively. The drive signal S+represented by S+=S0+′+Vbias is obtained by amplifying the acoustic signal S0+ centered on the bias voltage Vbias. The drive signal S− represented by S−=S0−′ obtained by amplifying the acoustic signal S0− centered on 0 V. Otherwise, the configuration of the drive circuit 55C is the same as that of the drive circuit 55B.

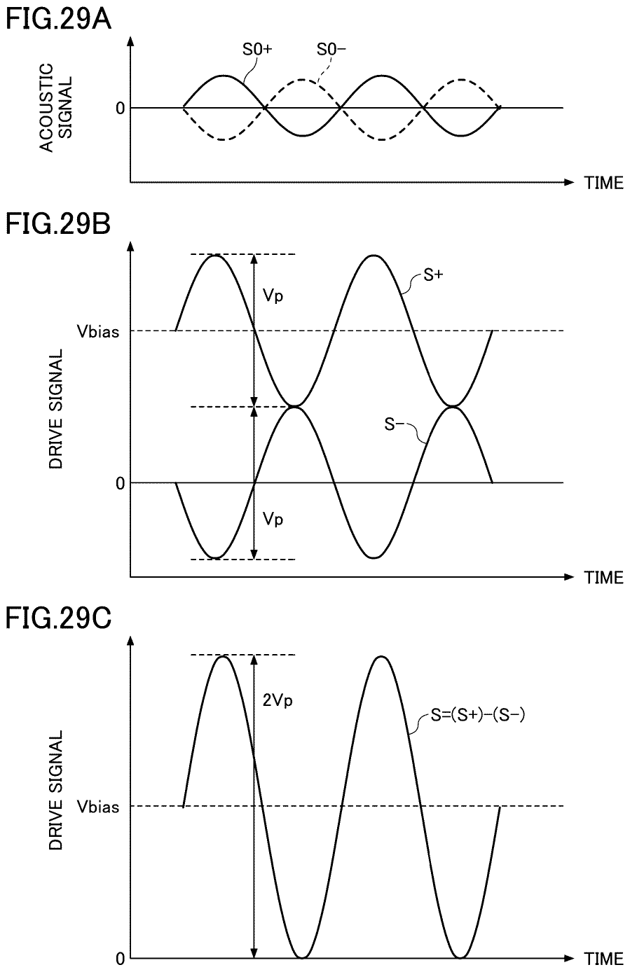

FIG. 29A, FIG. 29B, and FIG. 29C are diagrams illustrating signals with respect to the time in the third example of the drive circuit according to the third embodiment. FIG. 29A illustrates the acoustic signals S0+ and S0−. FIG. 29B illustrates the drive signals S+ and S−. FIG. 29C illustrates the drive signal S=(S+)−(S−).

As illustrated in FIG. 29A, the acoustic signals S0+ and S0− are signals centered on 0 V, and the acoustic signals S0+ and S0− are balanced signals having phases inverted relative to each other. As illustrated in FIG. 29B, the drive signal S+ is a signal centered on the bias voltage Vbias. The drive signal S− is a signal centered on 0 V. An amplitude Vp of the drive signal S+ and an amplitude Vp of the drive signal S− are identical, and the phase of the drive signal S+ is inverted relative to the phase of the drive signal S−, and the drive signal S+ and the drive signal S−are balanced signals. As illustrated in FIG. 29C, the drive signal S is centered on the bias voltage Vbias, and has an amplitude of 2×Vp.

Similar to the drive circuits 55A and 55B in the first and second examples of the drive circuit, the terminal T− of the piezoelectric element 30 may be set to the ground potential, and the drive signal S may be applied to the terminal T+. Similar to the drive circuit 55C in the third example of the drive circuit, the drive signals S+ and S− may be applied to the terminals T+ and T− of the piezoelectric element 30, respectively.

According to the fifth embodiment, the bias generation circuit 50 can adjust the bias voltage Vbias of the drive signal S supplied between the electrode 33 (second electrode) and the electrodes 31A and 31B (first electrodes). Hence, it is possible to adjust the bias voltage Vbias to a voltage that improves the characteristics of the speaker.

The drive circuits 55A, 55B, and 55C superimpose the acoustic signal S0 on the bias voltage Vbias. Accordingly, it is possible to generate the drive signal S superimposed on the bias voltage Vbias.

Similar to the first and second examples of the drive circuit, the electrodes 31A and 31B may be grounded, and the drive circuits 55A and 55B may supply the drive signal S to the electrode 33. Accordingly, it is possible to generate the drive signal using a simple circuit compared to the third example of the drive circuit.

Similar to the third example of the drive circuit, the drive circuit 55C may supply the drive signal S− (first drive signal) centered on 0 V (first bias voltage) to the electrodes 31A and 31B, and supply the drive signal S+ (second drive signal) centered on the bias voltage Vbias (second bias voltage) and having the phase inverted relative to the phase of the drive signal S− to the electrode 33. This configuration can increase the amplitude of the drive signal S applied between the electrode 33 and the electrodes 31A and 31B, compared to the first and second examples of the drive circuit.

When the drive signal S is not applied to the piezoelectric element 30 between the electrode 33 and the electrodes 31A and 31B, the chip is in the flat state. Thus, even when the stress-applying film 35 is not provided as in the second embodiment, the chip 10 can be brought into a state close to the flat state at the bias voltage Vbias as illustrated in FIG. 4B, by adjusting the bias voltage Vbias.

As illustrated in FIG. 4A, FIG. 4B, and FIG. 4C, when the drive signal S is not applied between the electrode 33 and the electrodes 31A and 31B, the movable portion 11 is positioned in the second direction 62 with respect to the flat state of the chip 10. This configuration enables the bias voltage Vbias to be adjusted even in the case where the stress-applying film 35 is provided as in the second embodiment.

In the case where the movable portion 11 is positioned in the second direction 62 with respect to the flat state of the chip 10, the bias voltage Vbias is adjusted to 0 V or to a voltage having the same polarity as when the drive signal having the maximum value Vmax is applied. Hence, it is possible to reduce the possibility of the piezoelectric layer 32 of the piezoelectric element 30 becoming depolarized. When the minimum value Vmin of the drive signal S is 0 V or a voltage having the same polarity as the maximum value Vmax, it is possible to further reduce the possibility of the piezoelectric layer 32 becoming depolarized.

The displacement of the movable portion 11 in the Z direction from the flat state of the chip 10 when the minimum value Vmin is applied between the electrode 33 and the electrodes 31A and 31B is denoted by D1. The displacement of the movable portion 11 in the Z direction from the flat state of the chip 10 when the maximum value Vmax is applied between the electrode 33 and the electrodes 31A and 31B is denoted by D2. In this case, the bias voltage Vbias is adjusted so that the displacement of the movable portion 11 in the Z direction from the flat state when the bias voltage Vbias is applied between the electrode 33 and the electrodes 31A and 31B is −0.25×|D2−D1| or greater and +0.25×|D2−D1| or less. Hence, it is possible to suppress deterioration of the characteristics, such as sound pressure, the linearity, or the like of the electroacoustic transducer. The displacement of the movable portion 11 in the Z direction from the flat state when the bias voltage Vbias is applied is more preferably −0.15×|D2−D1| or greater and +0.15×|D2−D1| or less, and even more preferably −0.1×|D2−D1| or greater and +0.1×|D2−D1| or less.

Although the embodiments and modifications are described above, the embodiments and modifications are presented as examples, and the present disclosure is not limited by the embodiments and modifications. The embodiments and modifications can be implemented in various other forms, and various combinations, omissions, substitutions, modifications, or the like can be made without departing from the gist and scope of the present disclosure. The embodiments and modifications are included in the gist and scope of the present disclosure including the claims and equivalents thereof.

According to the present disclosure, it is possible to suppress a decrease in the electroacoustic conversion characteristics.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An electroacoustic transducer comprising:
a chip including a movable portion, a frame portion surrounding the movable portion, and a connecting portion connecting the movable portion and the frame portion;
a piezoelectric element including a piezoelectric layer stacked on the connecting portion, and a first electrode and a second electrode configured to apply a voltage to the piezoelectric layer; and
a bias generation circuit configured to adjust a bias voltage of a drive signal to be applied between the first electrode and the second electrode.

2. The electroacoustic transducer as claimed in claim 1, wherein the chip is in a flat state when the drive signal is not applied between the first electrode and the second electrode.

3. The electroacoustic transducer as claimed in claim 1, wherein the movable portion is positioned in a second direction opposite to a first direction with respect to a flat state of the chip when the drive signal is not applied between the first electrode and the second electrode, when a direction from a position of the movable portion with respect to the frame portion in a state where the drive signal is not applied between the first electrode and the second electrode to a position of the movable portion with respect to the frame portion in a state where the bias voltage is applied between the first electrode and the second electrode is defined as the first direction.

4. The electroacoustic transducer as claimed in claim 1, further comprising:
a drive circuit configured to generate the drive signal by superimposing an acoustic signal on the bias voltage.

5. The electroacoustic transducer as claimed in claim 4, wherein the first electrode is grounded, and the drive circuit supplies the drive signal to the second electrode.

6. The electroacoustic transducer as claimed in claim 4, wherein:
the drive circuit supplies a first drive signal centered on a first bias voltage to the first electrode, and supplies a second drive signal centered on a second bias voltage to the second electrode, and
the second drive signal has a phase inverted relative to a phase of the first drive signal.

7. The electroacoustic transducer as claimed in claim 1, wherein a displacement of the movable portion in a first direction from the flat state of the chip when the bias voltage is applied between the first electrode and the second electrode is −0.25×|D2−D1| or greater and +0.25×|D2−D1| or less, when a direction from a position of the movable portion with respect to the frame portion in a state where the drive signal is not applied between the first electrode and the second electrode to a position of the movable portion with respect to the frame portion in a state where the bias voltage is applied between the first electrode and the second electrode is defined as the first direction, a displacement of the movable portion in the first direction from the flat state of the chip when the minimum value of the drive signal is applied between the first electrode and the second electrode is denoted by D1, and a displacement of the movable portion in the first direction from the flat state of the chip when a maximum value of the drive signal is applied between the first electrode and the second electrode is denoted by D2.

8. The electroacoustic transducer as claimed in claim 3, wherein the bias voltage is adjusted to 0 V or to a voltage having a polarity identical to that when the drive signal having a maximum value is applied between the first electrode and the second electrode.
